(19) United States
(12) Patent Application Publication
(10) Pub. No.: US 2024/0114800 A1
(43) Pub. Date: Apr. 4, 2024

(54) Deposition Of Piezoelectric Films

(71) Applicant: Applied Materials, Inc., Santa Clara, CA (US)

(72) Inventors: Vijay Bhan Sharma, Rajasthan (IN); Yuan Xue, Shaanxi (CN); Abhijeet Laxman Sangle, Maharashtra (IN); Bharatwaj Ramakrishnan, San Jose, CA (US); Yi Yang, Shaanxi (CN); Suresh Chand Seth, Mumbai (IN); Ankur Anant Kadam, Thane (IN)

(73) Assignee: Applied Materials, Inc., Santa Clara, CA (US)

(21) Appl. No.: 18/272,438

(22) PCT Filed: Jan. 18, 2021
(86) PCT No.: PCT/CN2021/072459

§ 371 Date: Jul. 14, 2023

(51) Int. Cl. H10N 30/853; C04B 35/493; C04B 35/499; C23C 14/02; C23C 14/08; C23C 14/34; C23C 14/58; C30B 23/02; C30B 23/08; C30B 29/30; C30B 29/32; C30B 33/02; H01J 37/34; H10N 30/00; H10N 30/04; H10N 30/076; H10N 30/079

(52) U.S. Cl. CPC H10N 30/8548; C04B 35/493; C04B 35/499; C23C 14/024; C23C 14/082; C23C 14/083; C23C 14/3407; C23C 14/5806; C30B 23/025; C30B 23/08; C30B 29/30; C30B 29/32; C30B 33/02; H01J 37/3426; H10N 30/04; H10N 30/076; H10N 30/079; H10N 30/10516; C04B 2235/3234; C04B 2235/3255; H01J 2237/332

(57) ABSTRACT

A piezoelectric device comprises: a substrate (12) and a lead magnesium niobate-lead titanate (PMNPT) piezoelectric film on the substrate (12). The PMNPT film comprises: a thermal oxide layer (20) on the substrate (12); a first electrode above on the thermal oxide layer (20); a seed layer (26) above the first electrode; a lead magnesium niobate-lead titanate (PMNPT) piezoelectric layer (16) on the seed layer (26), and a second electrode on the PMNPT piezoelectric layer (16). The PMNPT film comprises a piezoelectric coefficient (d33) of greater than or equal to 200 pm/V.

### TECHNICAL FIELD

Embodiments of the present disclosure generally relate to piezoelectric devices, and more particularly to deposition of piezoelectric films, in particular to physical vapor deposition of piezoelectric films.

### BACKGROUND

Piezoelectric materials have been used for several decades in a variety of technologies, e.g., ink jet printing, medical ultrasound and gyroscopes. Conventionally, piezoelectric layers are fabricated by producing a piezoelectric material in a bulk crystalline form and then machining the material to a desired thickness, or by using sol-gel techniques to deposit the layer. Lead zirconate titanate (PZT), typically of the form Pb[ZrxTi1-x]O₃, is a commonly used piezoelectric material.

More recently relaxor-lead titanate (relaxor-PT), such as (1-X)[Pb(Mg_{1/3}Nb_{2/3})O₃]—X[PbTiO₃] (PMNPT), (1-X)[Pb(Y_{1/3}Nb_{2/3})O₃]—X[PbTiO₃] (PYNPT), (1-X)[Pb(Zr_{1/3}Nb_{2/3})O₃]—X[PbTiO₃] (PZNPT), (1-X)[Pb(In_{1/3}Nb_{2/3})O₃]—X[PbTiO₃](PINPT), etc. have been proposed as better piezoelectric materials. Relaxor-PT can offer improved piezoelectric properties over the more commonly used PZT material.

There is a need for fabrication of high quality relaxor-PT layers and films, in particular PMNPT layers and films, over a useful area in a commercially viable manner.

### SUMMARY

One or more embodiments are directed to a piezoelectric device comprising: a substrate; a lead magnesium niobate-lead titanate (PMNPT) piezoelectric film on the substrate, the PMNPT piezoelectric film comprising: a thermal oxide layer on the substrate; a first electrode above on the thermal oxide layer; a seed layer above the first electrode; a lead magnesium niobate-lead titanate (PMNPT) piezoelectric layer on the seed layer; and a second electrode on the PMNPT piezoelectric layer; the PMNPT film comprising a piezoelectric coefficient (d33) of greater than or equal to 200 pm/V.

Additional embodiments are directed to a physical vapor deposition system comprising a conditioning chamber and a first support to hold a substrate in the conditioning chamber, the conditioning chamber being configured to provide a temperature of the substrate of 500° C.±50° C.; a deposition chamber and a second support to hold the substrate in the deposition chamber, the deposition chamber being configured to provide a temperature of the substrate of 650° C.±50° C.; a target in the deposition chamber comprising a piezoelectric material; and a power supply configured to apply power to the target to generate a plasma in the chamber to sputter the piezoelectric material from the target onto the substrate.

Further embodiments are directed to a method of fabricating a piezoelectric film, the method comprising: conditioning a substrate with a seed layer as an exposed layer in a conditioning chamber and setting a temperature of the substrate to 500° C.±50° C.; transferring the substrate to a processing chamber and setting a temperature of the substrate to 650° C.±50° C.; depositing a piezoelectric material onto the seed layer in a crystallographic phase in the processing chamber by physical vapor deposition to prepare a piezoelectric layer; and thermally annealing the substrate in the processing chamber to convert the piezoelectric layer to a final piezoelectric film.

### BRIEF DESCRIPTION OF THE DRAWINGS

FIG. 1 is a schematic cross-sectional illustration of a portion of a piezoelectric film, in particular a PMNPT film, comprising a stack of layers for fabrication of a device in accordance with one or more embodiments;

FIG. 2 is a flowchart of a method of fabricating a piezoelectric film in accordance with one or more embodiments;

FIG. 3 is a cluster tool accordance with one or more embodiments of the disclosure; and

FIG. 4 is a schematic cross-sectional view of an exemplary physical vapor deposition processing chamber.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed includes materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

As used herein, “consists essentially of” with respect to composition of a layer means that the stated elements compose greater than 95%, greater than 98%, greater than 99% or greater than 99.5% of the stated material on an atomic basis. For the avoidance of doubt, no stoichiometric ratios are implied by the identification of materials disclosed herein. For example, a SiO material contains silicon and oxygen. These elements may or may not be present at a 1:1 ratio.

Depositing a high quality lead magnesium niobate-lead titanate (PMNPT) thin film can be more challenging than depositing a lead zirconate titanate (PZT) thin film due to the presence of one more element in PMNPT as compared to PZT (five elements in PMNPT versus four elements in PZT). Provided herein are superior quality PMNPT thin layers with excellent resulting film qualities. According to one or more embodiments, PMNPT thin films and methods of their fabrication are particularly useful for micro electro mechanical systems (MEMS) sensors and actuators, which are suitable for ink jet printing, medical ultrasound, and gyroscopes.

Reference to a piezoelectric layer, for example, a relaxor-PT layer, in particular to a PMNPT layer, refers to a thickness of material resulting from deposition of a piezoelectric material, for example, a relaxor-PT material, and in particular a PMNPT material.

Reference to a piezoelectric film, for example, a relaxor-PT film, in particular to a PMNPT film, refers to a plurality of layers of one or more materials including a piezoelectric layer, for example, a relaxor-PT layer, and in particular a PMNPT layer. A final film may include an annealing treatment of an underlying layer.

Embodiments herein relate to piezoelectrc devices, physical vapor deposition systems, and methods of fabricating piezoelectric layers and films. The piezoelectric films advantageously comprise a piezoelectric coefficient (d33) of greater than or equal to 200 pm/V, including greater than or equal to 250 pm/V, greater than or equal to 300 pm/V, or greater than or equal to 330 pm/V.

Measurement by Double-Beam Laser Interferometry (DBLI) of a piezoelectric coefficient (d33) was 330 pm/V±10 pm/V for a PMNPT film fabricated as follows: a substrate with a seed layer comprising titanium was conditioned in a conditioning chamber, where a temperature of the substrate was set to 500° C.±50° C.; the substrate was transferred to a processing chamber, where a temperature of the substrate was set to 650° C.±50° C.; a PMNPT material was physical vapor deposition (PVD)-deposited onto the seed layer in a crystallographic phase; and the substrate was annealed in the processing chamber to yield a final PMNPT film. Thickness of the resulting film was 3 micrometers. Formation of the PMNPT film and a <001> crystallographic orientation was confirmed by measurement by x-ray diffraction (XRD). Scanning electronic microscope micrographs showed crystalline columnar grains and exclusive <001> crystallographic orientation of the resulting film. A piezoelectric coefficient (d33) for the underlying PMNPT layer prior to annealing was 300 pm/V±10 pm/V.

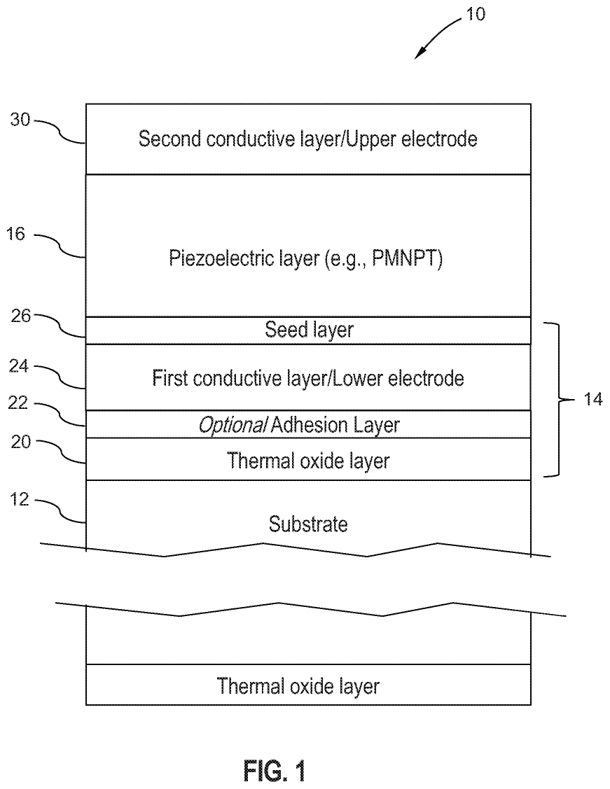

FIG. 1 illustrates a cross-section of a portion of a piezoelectric film, in particular a PMNPT film, comprising a stack of layers 10 for fabrication of a device. The stack of layers 10 comprises a piezoelectric layer 16, in particular a PMNPT layer, deposited on a substrate, e.g., a semiconductor wafer, 12. In particular, the stack 10 comprises one or more inner layers 14 between the substrate 12 and the piezoelectric layer 16. The one or more inner layers 14 includes a first conductive layer 24, which provides a lower electrode. The one or more layers 14 optionally include an adhesion layer 22 to improve adhesion of the conductive layer 24 to the substrate 12. A seed layer 26 promotes a desired crystalline orientation of the piezoelectric material in the piezoelectric layer 16. For some piezoelectric materials and/or conductive materials, the adhesion layer 22 is not required and can be absent. A thermal oxide layer 20 is on and/or in direct contact with one (or both) surfaces of the substrate 12. A second conductive layer 30, which provides an upper electrode, is on or above the piezoelectric layer 16.

In one or more embodiments, the substrate 12 is a semiconductor wafer, which can be a silicon wafer, or another semiconductor such as germanium (Ge). The silicon wafer can be a single crystal silicon wafer.

In one or more embodiments, as shown in FIG. 1, the inner layers 14 comprise, in order outward from the substrate 12: the thermal oxide layer 20, the optional adhesion layer 22, the lower conductive layer 24, and the seed layer 26.

In one or more embodiments, the thermal oxide layer 20 comprises one or more silicon oxides, including SiO₂, SiO, or combinations thereof. In one or more embodiments, the thermal oxide layer 20 has a thickness in a range of from about 50 to about 1000 nm. In one or more embodiments, the thermal oxide layer 20 is an amorphous layer.

In one or more embodiments, the adhesion layer 22 comprises a metal oxide. The stoichiometry of the metal oxide layer can include MO₂, M₂O₃, or MO (with M representing the metal element), or another suitable stoichiometry of the metal and oxygen. In one or more embodiments, the adhesion layer 22 comprises titanium oxide, e.g., TiO₂, Ti₂O₃, TiO, or anther stoichiometry of titanium and oxygen. In some implementations, rather than a metal oxide layer, the adhesion is a pure metal or a metal alloy. Examples for the metal (either for the metal of the metal oxide, or for the pure metal or component of the metal alloy) include titanium, chromium, chromium-nickel, and nickel. The adhesion layer 22 can be thinner than the thermal oxide layer 20. For example, a titanium oxide adhesion layer 22 can have a thickness in a range of about 25 to about 40 nm. The adhesion layer 22 can have a crystallographic orientation for facilitating a desired crystallographic orientation of the first conductive layer 24. For example, a TiO₂ layer can have a <001> orientation to facilitate a <111> orientation in a platinum conductive layer.

The first conductive layer 24 and the second conductive layer 30 are independently formed from conductive materials. In one or more embodiments, the second conductive layer 30 has the same material composition as the first conductive layer 24. Similarly, the first conductive layer 24 and the second conductive layer 30 have independent thicknesses. In one or more embodiments, the first conductive layer 24 and the second conductive layer 30 have independent thicknesses in a range of 50-300 nm. In one or more embodiments, the second conductive layer 30 has the same thickness as the first conductive layer 24.

In one or more embodiments, the first conductive layer 24 and the second conductive layer 30 independently comprise a conductive material, including but not limited to: platinum, gold, iridium, molybdenum, SrRuO₃, or combinations thereof. In one or more embodiments, the first conductive layer 24 is thicker than the adhesion layer 22, and/or is thicker than the thermal oxide layer 20. For example, the first conductive layer 24 can have a thickness in a range of about 50 to about 300 nm. The first conductive layer 24 can have a crystallographic orientation for facilitating a desired crystallographic orientation of the seed layer 26. For example, a platinum layer can have a <111> crystallographic orientation to facilitate a <001> orientation in a titanium oxide seed layer.

In one or more embodiments, the seed layer 26 is a metal oxide, in particular, an oxide of titanium or niobium. In one or more embodiments, the seed layer is TiO₂, Ti₂O₃, TiO, or another stoichiometry of titanium and oxygen. Desirably, the seed layer 26 has a uniform stoichiometry across the surface of the substrate 12. The seed layer 26 can have a crystallographic orientation for facilitating a desired crystallographic orientation of the piezoelectric layer 28. For example, a titanium oxide layer can have a suitable crystallographic orientation to facilitate a <001> orientation in a PMNPT piezoelectric layer. In one or more embodiments, the seed layer 26 is thinner than the adhesion layer 22. In one or more embodiments, the seed layer 26 has a thickness in a range of about 1 nm to about 5 nm, in particular, 2 nm±10%.

The piezoelectric layer 16 is deposited on the seed layer 26. Examples of material for the piezoelectric layer 16 include relaxor-PT materials. In particular, the material can be (1-x)[Pb(Mg_{(1-y)}Nb_{y})O₃]-x[PbTiO₃] (PMNPT), where x is about 0.2 to 0.8, and y is about 0.8 to 0.2, e.g., about ⅔. Due to the presence of the metal oxide seed layer, the PMNPT material can be predominantly, e.g., substantially entirely, a <001> crystallographic orientation. In one or more embodiments, the piezoelectric layer has a thickness in a range of about 50 nm to about 10 microns.

A voltage can be applied between the first conductive layers 24 and the second conductive layer 30 in order to actuate the piezoelectric layer 16. Thus, the first conductive layer provides a lower electrode 24 and the second conductive layer 30 provides an upper electrode with the piezoelectric layer 16 sandwiched therebetween.

To fabricate the stack of inner layers 14, the thermal oxide layer 20 is prepared by thermal processing of a thermal material, for example, silicon in an oxygen-containing atmosphere, yielding an oxide of SiO₂ grown on a Si <001> single crystal wafer. The thermal oxide can be grown to a thickness in a range of about 50 to about 1000 nm, for example, 100 nm. The thermal oxide can be formed on both sides of the silicon wafer.

When the optional adhesion layer is included, an adhesion material, for example, a metal, is deposited by PVD from a metal target in some embodiments. For example, the adhesion layer may comprise titanium. For example, the metal layer can be deposited on the substrate whose temperature is in a range of from room temperature (e.g., 25° C.) to 600° C.; and a power density of 0.5 to 20 Watts per square inch, e.g., about 1.5 Watts per square inch, applied to the target metal. Deposition of the adhesion layer can be followed by annealing in a rapid thermal processing chamber or furnace in the presence of oxygen or air to form the adhesion layer in the form of the metal oxide layer, e.g., TiOx. The annealing can be at a temperature of 500-800° C., e.g., for 2-30 minutes. The resulting adhesion layer can have a thickness in a range of about 5 nm to about 400.

The first conductive layer is deposited on the substrate. For example, on the adhesion layer (if present), on the silicon oxide (if present), or directly on the semiconductor wafer. For example, a platinum layer can be deposited on the substrate whose temperature is in a range of from room temperature (e.g., 25° C.) to 500° C., with a power density of 0.5 to 20 Watts per square inch, e.g., 4-5 Watts per square inch, applied to a platinum material target. Deposition of the first conductive layer can proceed until the layer has a thickness in a range of from about 50 to about 300 nm. The adhesion layer, if present, provides improved adhesion between the first conductive layer (e.g., platinum) and the thermal oxide layer (e.g., silicon oxide).

The seed layer 26 is generally a very thin metal layer, e.g., titanium, which is deposited on the lower electrode, e.g., the platinum layer, by a PVD (e.g., DC sputtering) or a CVD (e.g., ALD) technique. In particular, a titanium layer can be deposited, e.g., by DC sputtering. For example, the titanium seed layer can be deposited on the substrate whose temperature is in a range of from room temperature (e.g., 25° C.) to 500 C and a power density of 0.5 to 4 Watts per square inch, e.g., 1 Watt per square inch, applied to a titanium material target. In one or more embodiments, the seed layer has a thickness in a range of from about 1 nm to about 5 nm. The thin metal layer can then be oxidized, e.g., heated in an oxidizing atmosphere to convert the metal layer to a metal oxide, e.g., convert Ti to TiOx, to provide the seed layer. Additionally, the oxidized seed layer can also be deposited directly by a PVD or CVD technique, e.g., TiOx deposition by RF sputtering or ALD.

In one or more embodiments, a piezoelectric device comprises: a substrate and a lead magnesium niobate-lead titanate (PMNPT) piezoelectric film on the substrate. In one or more embodiments, the PMNPT piezoelectric film comprises: a thermal oxide layer on the substrate; a first electrode above on the thermal oxide layer; a seed layer above the first electrode; a lead magnesium niobate-lead titanate (PMNPT) piezoelectric layer on the seed layer; and a second electrode on the PMNPT piezoelectric layer.

In one or more embodiments, the PMNPT layer (prior to annealing) comprises a piezoelectric coefficient (d33) of greater than or equal to 170 pm/V, including greater than or equal to 220 pm/V, greater than or equal to 270 pm/V, or greater than or equal to 300 pm/V.

In one or more embodiments, the PMNPT film comprises a piezoelectric coefficient (d33) of greater than or equal to 200 pm/V, including greater than or equal to 250 pm/V, greater than or equal to 300 pm/V, or greater than or equal to 330 pm/V.

In some embodiments, the PMNPT piezoelectric film comprises: a thermal oxide layer of silicon oxide on the substrate; a first electrode of platinum above on the thermal oxide layer; a seed layer of a titanium oxide above the first electrode; a lead magnesium niobate-lead titanate (PMNPT) piezoelectric layer on the seed layer; and a second electrode of platinum on the PMNPT piezoelectric layer.

In one or more embodiments, the PMNPT piezoelectric layer comprises a thickness in a range of greater than or equal to 50 nanometers to less than or equal to 10 micrometers, including all values and subranges therebetween.

In one or more embodiments, the PMNPT film comprises a thickness in a range of greater than or equal to 1 micrometers to less than or equal to 5 micrometers, including all values and subranges therebetween.

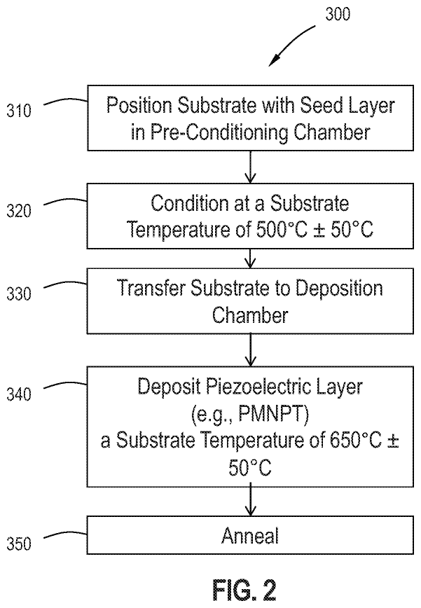

Turning to FIG. 2, provided is a flowchart of a method 300 of fabricating a piezoelectric film in accordance with one or more embodiments. At operation 310, a substrate with a seed layer is positioned in a pre-conditioning chamber. The seed layer of the substrate is exposed. Other layers as discussed with respect to FIG. 1 may be present between the seed layer and the substrate. In one or more embodiments, the conditioning chamber comprises a first support to hold the substrate in the conditioning chamber. At operation 320, the substrate, including the exposed seed layer is conditioned. The conditioning chamber is configured to provide a temperature of the substrate in a range of 450° C. to 550° C., e.g., 500° C.±50° C.

In one or more embodiments, the substrate resides in the conditioning chamber for a duration in a range of 5 seconds to 5 minutes.

At operation 330, the substrate is transferred from the pre-conditioning chamber to a deposition chamber. In one or more embodiments, the deposition chamber comprises a second support to hold the substrate in the deposition chamber. In one or more embodiments, operation 320 is conducted in a first chamber that is integrated with a second chamber where operation 340 is conducted, which allows for a transfer between the chambers without breaking vacuum and/or without exposure to ambient air.

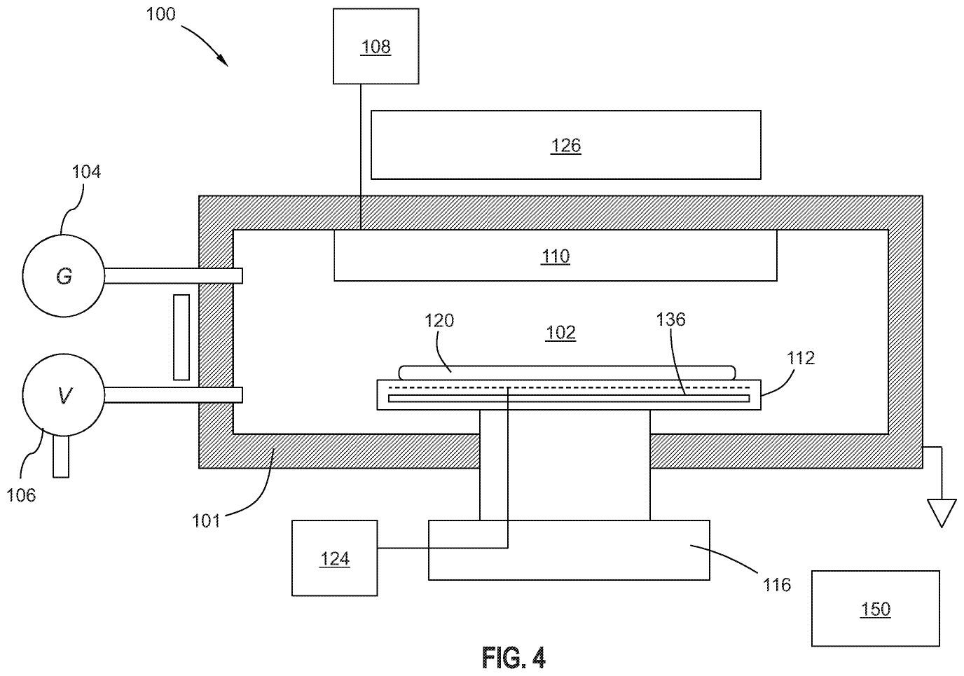

Next at operation 340, the piezoelectric layer is deposited on the seed layer. The deposition chamber is configured to provide a temperature of the substrate in a range of 600° C. to 700° C., e.g., 650° C.±50° C. Further discussion of the deposition chamber is provided with respect to FIG. 4. The piezoelectric layer is deposited by physical vapor deposition (PVD) of a piezoelectric material. In one or more embodiments, the piezoelectric material is a lead magnesium niobate-lead titanate (PMNPT) piezoelectric, including (1-x)[Pb(Mg_{(1-y)}Nb_{y})O₃]-x[PbTiO₃], where x is about 0.2 to 0.8, and y is about 0.8 to 0.2.

In one or more embodiments, the PVD treatment includes sputtering the piezoelectric material from a target in the deposition chamber. In particular, a piezoelectric layer is deposited while keeping the target at a relatively low temperature, e.g., no higher than 100° C. For example, the target can be kept at a temperature in a range of from room temperature (e.g., 25° C.) to 100° C. A cooling system in the ceiling of the deposition chamber can be used to cool the target.

In one or more embodiments, the physical vapor deposition of the piezoelectric material includes applying power to the target at a power less than 1.5 W/cm² of the target. Power applied to the target can be restricted to less than 1.5 W/cm², e.g., less than 1.2 W/cm². For example, for a 13 inch diameter target, the power source can apply about 1000 W power (in contrast a conventional PVD operation would be conducted at 1.5 kW to 5 kW). This lower power level results in less heat being generated in the target.

In one or more embodiments, the substrate resides in the deposition chamber for a duration in a range of 60 seconds to 30 minutes.

After deposition of the piezoelectric layer, at operation 350 the substrate is subjected to an annealing process. In one or more embodiments, the annealing process is an ex-situ thermal annealing. The substrate is removed from the deposition chamber and transferred to, for example, a furnace or rapid thermal processing system. The substrate can be heated to a temperature in a range for about 500° C. to about 750° C. In particular, for a piezoelectric layer formed of relaxor-PT material, the substrate can be heated to a temperature above the phase transition temperature between the perovskite and pyrochlore phases of the relaxor-PT material. For a piezoelectric layer that is about 70% PMN and 30% PT, the substrate should be raised to a temperature of about 750° C. or higher.

The temperature of the substrate should be raised with sufficient speed to limit formation of piezoelectric crystals in the pyrochlore phase, e.g. to below 50%. For example, the temperature can be raised from room temperature at a rate of 10-50° C. per second until the desired temperature is reached. Without being limited to any particular theory, the energy required for piezoelectric materials such as PMNPT to transition from the pyrochlore phase to the perovskite phase can be greater than the energy required to transition from the amorphous phase to the perovskite phase. Thus, if temperature is raised slowly, the piezoelectric material can enter and become “locked in” the pyrochlore phase. However, if the temperature is raised sufficiently rapidly, the piezoelectric material does not have sufficient time to form crystals in the pyrochlore phase.

The annealing can be conducted in a regular atmosphere, pure oxygen environment, pure nitrogen environment, a mixture of pure oxygen and nitrogen or in vacuum. Presence of oxygen during annealing can affect stoichiometry of the piezoelectric layer.

The annealing can significantly change crystalline grain size. After annealing, the piezoelectric coefficient d33 of the film is greater than the piezoelectric coefficient d33 of the layer.

Consistent with the foregoing, methods of this disclosure can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, a suitable processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, anneal, orientation, hydroxylation and other substrate processes. By carrying out processes in a chamber on a cluster tool, surface contamination of the substrate with atmospheric impurities can be avoided without oxidation prior to depositing a subsequent film.

In some embodiments, the first processing chamber and the second processing chamber are part of the same, clustered, processing tool. Accordingly, in some embodiments, the method is an in-situ integrated method.

In some embodiments, the first processing chamber and the second processing chamber are different processing tools. Accordingly, in some embodiments, the method is an ex-situ integrated method.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, and/or cleaning processes throughout the carousel path.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

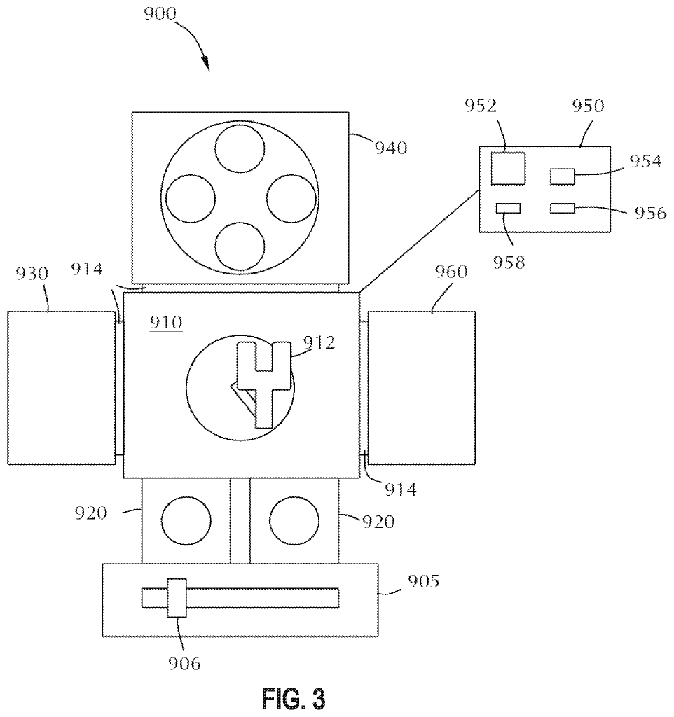

FIG. 3 illustrates a system 900 that can be used to process a substrate according to one or more embodiments of the disclosure. The system 900 can be referred to as a cluster tool. The system 900 includes a central transfer station 910 with a robot 912 therein. The robot 912 is illustrated as a single blade robot; however, those skilled in the art will recognize that other robot 912 configurations are within the scope of the disclosure. The robot 912 is configured to move one or more substrates between chambers connected to the central transfer station 910.

At least one conditioning chamber 920, which may be referred to as a pre-clean/buffer chamber is connected to the central transfer station 910. The conditioning chamber 920 can include one or more of a heater, a radical source or plasma source. The conditioning chamber 920 can be used for preconditioning the substrates herein prior to deposition. The conditioning chamber 920 pre-heats the substrate for processing. In some embodiments, there are two conditioning chambers 920 connected to the central transfer station 910.

A processing chamber 930 can be connected to the central transfer station 910. The processing chamber 930 can be configured as a physical vapor deposition chamber for depositing a piezoelectric material onto a seed layer and may be in fluid communication with one or more reactive gas sources to provide one or more flows of reactive gases to the processing chamber 930. The substrate can be moved to and from the processing chamber 930 by the robot 912 passing through isolation valve 914.

Other processing chambers 940 and 960 can also be connected to the central transfer station 910 for any further desired processing. The substrate can be moved to and from the processing chamber 940 by robot 912 passing through isolation valve 914. The substrate can be moved to and from the processing chamber 960 by robot 912 passing through isolation valve 914.

In some embodiments, each of the processing chambers 930, 940, and 960 is configured to perform different portions of the processing method.

In some embodiments, the processing system 900 includes one or more metrology stations. For example metrology stations can be located within pre-clean/buffer chamber 920, within the central transfer station 910 or within any of the individual processing chambers. The metrology station can be any position within the system 900 that allows the distance of the recess to be measured without exposing the substrate to an oxidizing environment.

At least one controller 950 is coupled to one or more of the central transfer station 910, the pre-clean/buffer chamber 920, processing chambers 930, 940, or 960. In some embodiments, there are more than one controller 950 connected to the individual chambers or stations and a primary control processor is coupled to each of the separate processors to control the system 900. The controller 950 may be one of any form of general-purpose computer processor, microcontroller, microprocessor, etc., that can be used in an industrial setting for controlling various chambers and sub-processors.

The at least one controller 950 can have a processor 952, a memory 954 coupled to the processor 952, input/output devices 956 coupled to the processor 952, and support circuits 958 to communication between the different electronic components. The memory 954 can include one or more of transitory memory (e.g., random access memory) and non-transitory memory (e.g., storage).

The memory 954, or computer-readable medium, of the processor may be one or more of readily available memory such as random access memory (RAM), read-only memory (ROM), floppy disk, hard disk, or any other form of digital storage, local or remote. The memory 954 can retain an instruction set that is operable by the processor 952 to control parameters and components of the system 900. The support circuits 958 are coupled to the processor 952 for supporting the processor in a conventional manner. Circuits may include, for example, cache, power supplies, clock circuits, input/output circuitry, subsystems, and the like.

FIG. 4 depicts a schematic representation of a chamber 100 of an integrated processing system, e.g., an ENDURA system, suitable for practicing the physical vapor deposition process discussed herein. The processing system can include multiple chambers, which can be adapted for PVD or CVD processes. For example, the processing system can include a cluster of interconnected process chambers, for example, a CVD chamber and a PVD chamber.

The chamber 100 includes chamber walls 101 that surround a vacuum chamber 102, a gas source 104, a pumping system 106 and a target power source 108. Inside the vacuum chamber 102 is a target 110 and a pedestal 112 to support the substrate 120. A shield can be placed inside the chamber to enclose a reaction zone. The pedestal can be vertically movable, and a lift mechanism 116 can be coupled to the pedestal 112 to position the pedestal 112 relative to the target 110. A heater or chiller 136, e.g., a resistive heater or a thermoelectric chiller, can be embedded in the pedestal 112 to maintain the substrate 120 at a desired process temperature.

The target 110 is composed of the material to be deposited, e.g., lead magnesium niobate-lead titanate for PMNPT. However, the target can have an excess of PbOₓ relative to the desired stoichiometry for the layer to be deposited to account for the loss of lead due to its volatile nature. For example, the target can have an excess of PbO of 1-20 mol %. The target itself should be of homogenous composition. he target 110 can be platinum (Pt) or Titanium (Ti) for deposition of other layers.

The gas source 104 can introduce an inert gas, e.g., argon (Ar) or xenon (Xe), or a mixture of an inert gas with a processing gas, e.g., oxygen, into the vacuum chamber 102. The chamber pressure is controlled by the pumping system 106. The target power source 108 may include a DC source, a radio frequency (RF) source, or a DC-pulsed source.

In operation, the substrate 120 is supported within the chamber 102 by the pedestal 112, gas from the source 104 flows into the chamber 102, and the target power source 108 applies power to the target 110 at a frequency and voltage to generate a plasma in the chamber 102. The target materials are sputtered from the target 110 by the plasma, and deposited on the substrate 120.

If the target power source 108 is DC or DC-pulsed, then the target 110 acts as a negatively biased cathode and the shield is a grounded anode. For example, a plasma is generated from the inert gas by applying a DC bias to the sputtering target 210 sufficient to generate a power density of about 0.5 to 350 Watts per square inch, e.g., 100-38,000 W for a 13 inch diameter target, and more typically about 100-10,000 W. If the target power source 108 is an RF source, then the shield is typically grounded and the voltage at the target 110 varies relative to the shield at a radio frequency, typically 13.56 MHz. In this case, electrons in the plasma accumulate at the target 110 to create a self-bias voltage that negatively biases the target 110.

The chamber 100 may include additional components for improving the sputtering deposition process. For example, a power source 124 may be coupled to the pedestal 112 for biasing the substrate 120, in order to control the deposition of the film on the substrate 120. The power source 124 is typically an AC source having a frequency of, for example, between about 350 to about 450 kHz. When the bias is applied by the power source 124, a negative DC offset is created (due to electron accumulation) at the substrate 120 and the pedestal 112. The negative bias at the substrate 120 attracts sputtered target material that becomes ionized. The target material is generally attracted to the substrate 120 in a direction that is substantially orthogonal to the substrate 120. As such, the bias power source 124 improves the step coverage of deposited material compared to an unbiased substrate 120.

The chamber 100 may also have a magnet 126 or magnetic sub-assembly positioned behind the target 110 for creating a magnetic field proximate to the target 110. In some implementations, the magnet rotates during the deposition process.

The operation of the chamber can be controlled by a controller 150, e.g., a dedicated microprocessor, e.g., an ASIC, or a conventional computer system executing a computer program stored in a non-volatile computer readable medium. The controller 150 can include a central processor unit (CPU) and memory containing the associated control software.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A piezoelectric device comprising:
a substrate;
a lead magnesium niobate-lead titanate (PMNPT) piezoelectric film on the substrate, the PMNPT piezoelectric film comprising:
a thermal oxide layer on the substrate;
a first electrode above on the thermal oxide layer;
a seed layer above the first electrode;
a lead magnesium niobate-lead titanate (PMNPT) piezoelectric layer on the seed layer; and
a second electrode on the PMNPT piezoelectric layer;
the PMNPT film comprising a piezoelectric coefficient (d33) of greater than or equal to 200 pm/V.

2. The piezoelectric device of claim 1, wherein the piezoelectric coefficient (d33) is greater than or equal to 250 pm/V.

3. The piezoelectric device of claim 2, wherein the piezoelectric coefficient (d33) is greater than or equal to 330 pm/V.

4. The piezoelectric device of claim 1, wherein the PMNPT film comprises a thickness in a range of greater than or equal to 1 micrometers to less than or equal to 5 micrometers.

5. The piezoelectric device of claim 1, wherein the PMNPT piezoelectric layer comprises a thickness in a range of greater than or equal to 50 nanometers to less than or equal to 10 micrometers.

6. The piezoelectric device of claim 1, wherein the substrate comprises silicon and the thermal oxide layer comprises silicon oxide.

7. The device of claim 1, wherein the PMNPT piezoelectric layer comprises a material that is: (1-x)[Pb(Mg_{(1-y)}Nb_{y})O₃]-x[PbTiO₃], where x is about 0.2 to 0.8, and y is about 0.8 to 0.2.

8. The piezoelectric device of claim 1, wherein the PMNPT piezoelectric layer comprises a crystallographic orientation of <001>.

9. A physical vapor deposition system comprising:
a conditioning chamber and a first support to hold a substrate in the conditioning chamber, the conditioning chamber being configured to provide a temperature of the substrate of 500° C.±50° C.;
a deposition chamber and a second support to hold the substrate in the deposition chamber, the deposition chamber being configured to provide a temperature of the substrate of 650° C.±50° C.;
a target in the deposition chamber comprising a piezoelectric material; and
a power supply configured to apply power to the target to generate a plasma in the deposition chamber to sputter the piezoelectric material from the target onto the substrate.

10. The physical vapor deposition system of claim 9, wherein the piezoelectric material is a lead magnesium niobate-lead titanate (PMNPT) piezoelectric.

11. The physical vapor deposition system of claim 10, wherein the piezoelectric material comprises (1-x)[Pb(Mg_{(1-y)}Nb_{y})O₃]-x[PbTiO₃], where x is about 0.2 to 0.8, and y is about 0.8 to 0.2.

12. A method of fabricating a piezoelectric film, the method comprising:
conditioning a substrate with a seed layer as an exposed layer in a conditioning chamber and setting a temperature of the substrate to 500° C.±50° C.;
transferring the substrate to a processing chamber and setting a temperature of the substrate to 650° C.±50° C.;
depositing a piezoelectric material onto the seed layer in a crystallographic phase in the processing chamber by physical vapor deposition to prepare a piezoelectric layer; and
thermally annealing the substrate in the processing chamber to convert the piezoelectric layer to a final piezoelectric film.

13. The method claim 12, wherein the seed layer comprises an oxide of titanium or niobium.

14. The method of claim 12, wherein the crystallographic phase is a crystallographic orientation of <001>.

15. The method of claim 12, wherein the piezoelectric material is a lead magnesium niobate-lead titanate (PMNPT) piezoelectric.

16. The method of claim 15, wherein the piezoelectric layer comprises a material that is: (1-x)[Pb(Mg_{(1-y)}Nb_{y})O₃]-x[PbTiO₃], where x is about 0.2 to 0.8, and y is about 0.8 to 0.2.

17. The method of claim 12, wherein the physical vapor deposition includes sputtering the piezoelectric material from a target in the processing chamber.

18. The method of claim 17, wherein the physical vapor deposition includes applying power to the target at a power less than 1.5 W/cm² of the target.

19. The method of claim 12, wherein the substrate resides in the conditioning chamber for a duration in a range of 5 seconds to 5 minutes.

20. The method of claim 12, wherein the substrate resides in the processing chamber for a duration in a range of 60 seconds to 30 minutes.
